(19) United States
(12) Patent Application Publication
(10) Pub. No.: US 2024/0396540 A1
(43) Pub. Date: Nov. 28, 2024

(54) INVERTER-BASED COMPARATOR

(71) Applicants: National Cheng Kung University, Tainan City (TW); Himax Technologies Limited, Tainan City (TW)

(72) Inventors: Philex Ming-Yan Fan, Tainan City (TW); Yi-Fu Chen, Tainan City (TW); Bo-Rui Chen, Tainan City (TW)

(21) Appl. No.: 18/797,259

(22) Filed: Aug. 7, 2024

Related U.S. Application Data
(63) Continuation-in-part of application No. 18/095,399, filed on Jan. 10, 2023.

(51) Int. Cl. H03K 5/24

(52) U.S. Cl. CPC H03K 5/2472

(57) ABSTRACT

An inverter-based comparator includes an output stage circuit including a P-type output transistor and an N-type output transistor; a first inverter having a first transition voltage with an input node coupled to an input voltage and an output node generating a first inverted voltage and coupled to a gate of the N-type output transistor; and a second inverter having a second transition voltage with an input node coupled to the input voltage and an output node generating a second inverted voltage and coupled to a gate of the P-type output transistor. The first inverter and the second inverter each includes an inverter that includes a first inverter branch composed of at least one first P-type transistor and at least one first N-type transistor; and a second inverter branch composed of at least one second P-type transistor, at least one second N-type transistor and at least two tuning switches.

### CROSS-REFERENCE TO RELATED APPLICATIONS

This application is a continuation-in-part (CIP) application of U.S. application Ser. No. 18/095,399, filed on Jan. 10, 2023, the entire contents of which are herein expressly incorporated by reference.

### BACKGROUND OF THE INVENTION

### 1. Field of the Invention

The present invention generally relates to a comparator, and more particularly to an inverter-based comparator.

### 2. Description of Related Art

Power management integrated circuit (PMIC) is designed to controllably switch a system to a low-power state when inactive, in order to obtain high power conversion efficiency in static operating mode, thereby substantially extending the battery lifetime, for example, in a low power consumption system such as Internet of things (IoT).

Conventional power management ICs use a comparator or an error amplifier for monitoring the output voltage to ensure a stable output voltage and proper load performance. Accordingly, the power management ICs demand always-on comparator or error amplifier, which nonetheless consumes non-negligible power, reduces power conversion efficiency and increases quiescent power, thereby resulting in reduced battery lifetime.

Moreover, the comparator adopted in the conventional power management ICs makes comparison by comparing the input voltage with a reference voltage, which is externally generated by a reference voltage generating circuit that consumes extra power and circuit area. Further, traditional low-power comparators are susceptible to noise, especially in noisy environments.

A need has thus arisen to propose a novel low-power comparator adaptable to low-power power management systems, and capable of mitigating noise in low-power comparators, making them more robust in noisy environments.

### SUMMARY OF THE INVENTION

In view of the foregoing, it is an object of the embodiment of the present invention to provide an inverter-based comparator with a cascoded inverter capable of substantially reducing power consumption and tuning a trigger point thereof, and with hysteresis adaptable to operating with a noisy input voltage in noisy environments.

According to one embodiment, an inverter-based comparator, powered between a first supply voltage and a second supply voltage being lower than the first supply voltage, includes a first inverter branch and a second inverter branch. The first inverter branch is composed of at least one first P-type transistor and at least one first N-type transistor. The second inverter branch is composed of at least one second P-type transistor, at least one second N-type transistor and at least two tuning switches. The first inverter branch and the second inverter branch are configured to compare an input voltage with an internal trigger point, thereby generating a compare voltage at an interconnected node. One of the at least two tuning switches is controlled to isolate the first supply voltage and another is controlled to isolate the second supply voltage to compensate for trigger point shifting.

According to another embodiment, an inverter-based comparator includes an output stage circuit, a first inverter and a second inverter. The output stage circuit includes a P-type output transistor and an N-type output transistor electrically connected in series in an order from a first supply voltage to a second supply voltage being lower than the first supply voltage, and electrically connected at an output node that provides an output voltage. The first inverter has a first transition voltage with an input node coupled to an input voltage and an output node generating a first inverted voltage and coupled to a gate of the N-type output transistor. The second inverter has a second transition voltage with an input node coupled to the input voltage and an output node generating a second inverted voltage and coupled to a gate of the P-type output transistor, the second transition voltage being greater than the first transition voltage. The first inverter and the second inverter each includes an inverter that includes a first inverter branch and a second inverter branch. The first inverter branch is composed of at least one first P-type transistor and at least one first N-type transistor. The second inverter branch is composed of at least one second P-type transistor, at least one second N-type transistor and at least two tuning switches. The first inverter branch and the second inverter branch are configured to compare the input voltage with an internal trigger point, thereby generating a compare voltage as an inverted voltage of the first inverter or the second inverter at an interconnected node. One of the at least two tuning switches is controlled to isolate the first supply voltage and another is controlled to isolate the second supply voltage to generate the first transition voltage or the second transition voltage.

According to a further embodiment, an inverter-based comparator powered between a first supply voltage and a second supply voltage being lower than the first supply voltage includes a first inverter, a second inverter and an inverter. The first inverter has a first transition voltage with an input node coupled to an input voltage and an output node generating a first inverted voltage. The second inverter has a second transition voltage with an input node coupled to the input voltage and an output node generating a second inverted voltage, the second transition voltage being greater than the first transition voltage. The inverter is composed of a first inverter branch and a second inverter branch. The first inverter branch is composed of at least one first P-type transistor coupled to the second inverted voltage and at least one first N-type transistor coupled to the first inverted voltage. The second inverter branch is composed of at least one second P-type transistor coupled to the second inverted voltage, at least one second N-type transistor coupled to the first inverted voltage and at least two tuning switches. The first inverter branch and the second inverter branch are configured to compare the first inverted voltage and the second inverted voltage with an internal trigger point, thereby generating a compare voltage as an output voltage at an interconnected node. One of the at least two tuning switches is controlled to isolate the first supply voltage and another is controlled to isolate the second supply voltage to compensate for trigger point shifting.

### BRIEF DESCRIPTION OF THE DRAWINGS

FIG. 1 shows a block diagram illustrating an inverter-based comparator adaptable to low-power power management systems according to one embodiment of the present invention;

FIG. 2 shows a circuit diagram exemplifying the inverter-based comparator of FIG. 1;

FIG. 3 shows a detailed circuit diagram illustrating the inverter of FIG. 2 according to one embodiment of the present invention;

FIG. 4 shows a circuit diagram illustrating the first inverter branch of FIG. 3 according to another embodiment of the present invention;

FIG. 5 shows a circuit diagram illustrating an inverter-based comparator according to one embodiment of the present invention;

FIG. 6 shows a characteristic curve when operating the inverter-based comparator of FIG. 5; and

FIG. 7 shows a circuit diagram illustrating an inverter-based comparator according to another embodiment of the present invention.

### DETAILED DESCRIPTION OF THE INVENTION

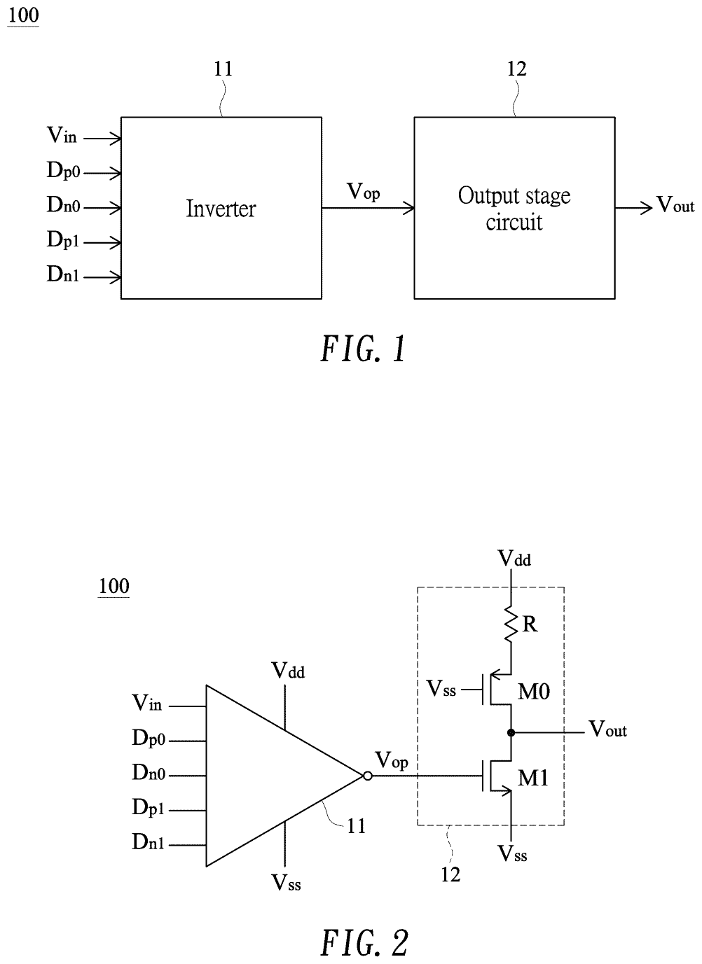

FIG. 1 shows a block diagram illustrating an inverter-based comparator 100 adaptable to low-power power management systems according to one embodiment of the present invention, and FIG. 2 shows a circuit diagram exemplifying the inverter-based comparator 100 of FIG. 1.

In the embodiment, the inverter-based comparator 100 may include an inverter 11 coupled to receive an input voltage Vᵢₙ and configured to compare the input voltage Vᵢₙ with an (internal) trigger point that is internally determined according to the inverter 11 itself, thereby generating a compare voltage Vₒₚ indicating comparison result. As the inverter 11 of the inverter-based comparator 100 makes comparison by comparing the input voltage Vᵢₙ with the internally generated trigger point, instead of an externally provided reference voltage, the inverter-based comparator 100 can substantially reduce power consumption and circuit area. In one embodiment, the inverter 11 is preferably a cascoded inverter, which adopts a cascode structure acquiring more transistor channel length, and current leakage when the input voltage Vᵢₙ is near the trigger point can be greatly reduced, thereby further reducing overall power consumption.

According to one aspect of the embodiment, the trigger point of the inverter 11 may be tuned (or adjusted) by at least one (e.g., digital) tuning signal (Dₙ₀-Dₙ₁ and Dₚ₀-Dₚ₁ as exemplified in FIG. 1 and FIG. 2) that is externally provided, in order to compensate for trigger point shifting due to process variation.

The inverter-based comparator 100 of the embodiment may include an output stage circuit 12 coupled to receive the compare voltage Vₒₚ and configured to ensure a state for the compare voltage Vₒₚ, thereby generating an output voltage Vₒᵤₜ at an output node (of the inverter-based comparator 100).

Specifically, the output stage circuit 12 may include a resistor R, a P-type transistor (e.g., P-type metal-oxide-semiconductor (PMOS) transistor) M0 and an N-type transistor (e.g., N-type metal-oxide-semiconductor (NMOS) transistor) M1, which are connected in series in an order from a first supply voltage (e.g., positive supply voltage V_{dd}) to a second supply voltage (e.g., negative supply voltage Vₛₛ) being lower than the first supply voltage, with a gate of the PMOS transistor M0 coupled to the second supply voltage Vₛₛ, a gate of the NMOS transistor M1 coupled to the compare voltage Vₒₚ, and drains of the PMOS transistor M0 and the NMOS transistor M1 connected at the output node (of the inverter-based comparator 100) for providing the output voltage Vₒᵤₜ.

In operation, when a gate-to-source voltage of the NMOS transistor M1 is greater than a corresponding threshold voltage, the NMOS transistor M1 is turned on and the output voltage Vₒᵤₜ is pulled down to the second supply voltage Vₛₛ, otherwise the NMOS transistor M1 is turned off and the output voltage Vₒᵤₜ is pulled up to the first supply voltage V_{dd} via the resistor R, thereby ensuring that the output voltage Vₒᵤₜ represents the state of the compare voltage Vₒₚ.

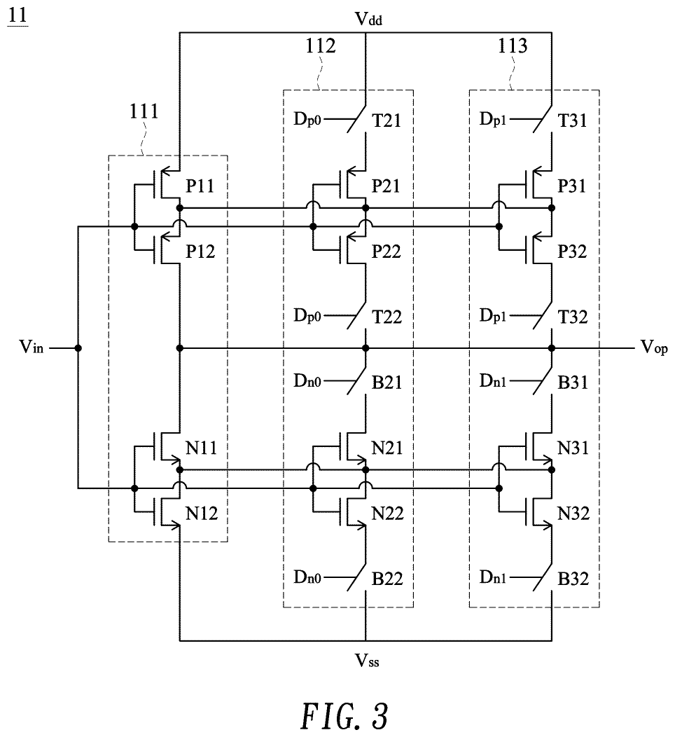

FIG. 3 shows a detailed circuit diagram illustrating the inverter (preferably a cascoded inverter) 11 of FIG. 2 according to one embodiment of the present invention.

Specifically, the cascoded inverter 11 of the embodiment may include a first inverter branch 111 composed of series-connected first PMOS transistors P11-P12 and series-connected first NMOS transistors N11-N12, which are electrically connected in series in the order from the first supply voltage V_{dd} to the second supply voltage Vₛₛ. Gates of the series-connected first PMOS transistors P11-P12 and the series-connected first NMOS transistors N11-N12 are coupled to the input voltage Vᵢₙ, and an interconnected node electrically coupled between the series-connected first PMOS transistors P11-P12 and the series-connected first NMOS transistors N11-N12 provides the compare voltage Vₒₚ. Alternatively, for a non-cascode embodiment, the first inverter branch 111 may be composed of a first PMOS transistor P11 and a first NMOS transistor N11, which are electrically connected in series in the order from the first supply voltage V_{dd} to the second supply voltage Vₛₛ.

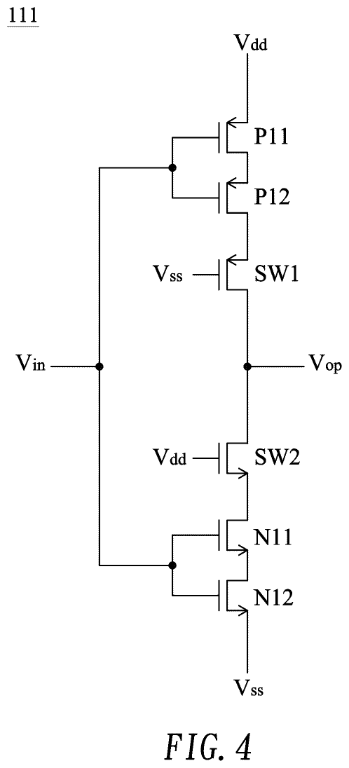

FIG. 4 shows a circuit diagram illustrating the first inverter branch 111 of FIG. 3 according to another embodiment of the present invention. Specifically, the first inverter branch 111 may further include a first switch SW1 (e.g., PMOS transistor) connected between the series-connected first PMOS transistors P11-P12 and the interconnected node Vₒₚ, and a second switch SW2 (e.g., NMOS transistor) connected between the series-connected first NMOS transistors N11-N12 and the interconnected node Vₒₚ. The gate of the first switch SW1 may, for example, be coupled to the second supply voltage Vₛₛ, and the gate of the second switch SW2 may, for example, be coupled to the first supply voltage V_{dd} as exemplified in FIG. 4.

Referring back to FIG. 3, the cascoded inverter 11 of the embodiment may include a second inverter branch 112 composed of series-connected second PMOS transistors P21-P22 and series-connected second NMOS transistors N21-N22, which are electrically connected in series in the order from the first supply voltage V_{dd} to the second supply voltage Vₛₛ. Gates of the series-connected second PMOS transistors P21-P22 and the series-connected second NMOS transistors N21-N22 are coupled to the input voltage Vᵢₙ, and the series-connected second PMOS transistors P21-P22 and the series-connected second NMOS transistors N21-N22 are electrically connected at the interconnected node that provides the compare voltage Vₒₚ. Alternatively, for a non-cascode embodiment, the second inverter branch 112 may be composed of a second PMOS transistor P21 and a second NMOS transistor N21, which are electrically connected in series in the order from the first supply voltage V_{dd} to the second supply voltage Vₛₛ. Moreover, the first switch SW1 and the second switch SW2 as illustrated in FIG. 4 may be adopted in the second inverter branch 112.

According to one aspect of the embodiment, the second inverter branch 112 may further include at least two tuning switches controlled by at least one tuning signal, and configured to isolate the first supply voltage V_{dd} and the second supply voltage Vₛₛ respectively. Each tuning switch may be composed of one MOS transistor, or be composed of two MOS transistors connected in parallel to act as a transmission gate. In one embodiment, the at least two tuning switches may include a top switch (controlled by a first tuning signal Dₚ₀) connected between the first supply voltage V_{dd} and the series-connected second PMOS transistors P21-P22 as denoted by T21, or connected between the series-connected second PMOS transistors P21-P22 and the interconnected node Vₒₚ as denoted by T22; and include a bottom switch (controlled by a second tuning signal Dₙ₀) connected between the interconnected node Vₒₚ and the series-connected second NMOS transistors N21-N22 as denoted by B21, or connected between the series-connected second NMOS transistors N21-N22 and the second supply voltage Vₛₛ as denoted by B22. In an alternative embodiment, the at least two tuning switches may include two top switches T21 and T22, and include two bottom switches B21 and B22.

Similarly, the cascoded inverter 11 of the embodiment may optionally include an third inverter branch 113 composed of series-connected third PMOS transistors P31-P32 and series-connected third NMOS transistors N31-N32, which are electrically connected in series in the order from the first supply voltage V_{dd} to the second supply voltage Vₛₛ. Gates of the series-connected third PMOS transistors P31-P32 and the series-connected third NMOS transistors N31-N32 are coupled to the input voltage Vᵢₙ, and the series-connected third PMOS transistors P31-P32 and the series-connected third NMOS transistors N31-N32 are electrically connected at the interconnected node that provides the compare voltage Vₒₚ. Alternatively, for a non-cascode embodiment, the third inverter branch 113 may be composed of a third PMOS transistor P31 and a third NMOS transistor N31, which are electrically connected in series in the order from the first supply voltage V_{dd} to the second supply voltage Vₛₛ. Moreover, the first switch SW1 and the second switch SW2 as illustrated in FIG. 4 may be adopted in the third inverter branch 113. It is appreciated that, in another embodiment, the third inverter branch 113 may be omitted or a fourth inverter branch or branches like the second/third inverter branch 112/113 may be further included.

According to the aspect of the embodiment, the third inverter branch 113 may further include at least two tuning switches controlled by at least one tuning signal, and configured to isolate the first supply voltage V_{dd} and the second supply voltage Vₛₛ, respectively. Each tuning switch may be composed of one MOS transistor, or be composed of two MOS transistors connected in parallel to act as a transmission gate. In one embodiment, the at least two tuning switches may include a top switch (controlled by a third tuning signal Dₚ₁) connected between the first supply voltage V_{dd} and the series-connected third PMOS transistors P31-P32 as denoted by T31, or connected between the series-connected third PMOS transistors P31-P32 and the interconnected node Vₒₚ as denoted by T32; and include a bottom switch (controlled by a fourth tuning signal Dₙ₁) connected between the interconnected node Vₒₚ and the series-connected third NMOS transistors N31-N32 as denoted by B31, or connected between the series-connected third NMOS transistors N31-N32 and the second supply voltage Vₛₛ as denoted by B32. In an alternative embodiment, the at least two tuning switches may include two top switches T31 and T32, and include two bottom switches B31 and B32. Interlinked nodes of the series-connected first PMOS transistors P11-P12, the series-connected second PMOS transistors P21-P22 and the series-connected third PMOS transistors P31-P32 may be connected together, and interlinked node of the series-connected first NMOS transistors N11-N12, the series-connected second NMOS transistors N21-N22 and the series-connected third NMOS transistors N31-N32 may be connected together.

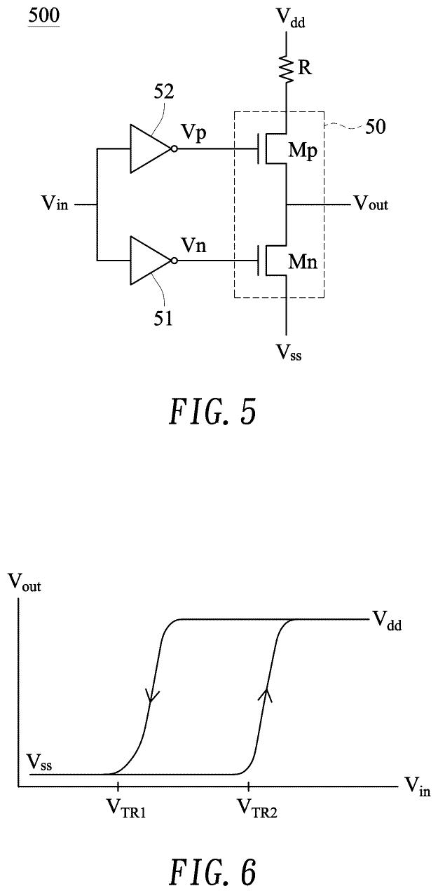

FIG. 5 shows a circuit diagram illustrating an inverter-based comparator 500 according to one embodiment of the present invention.

In the embodiment, the inverter-based comparator 500 may include an output stage circuit 50 electrically connected between a first supply voltage V_{dd} and a second supply voltage Vₛₛ, which may be ground in other embodiments. Specifically, the output stage circuit 50 may include a P-type output transistor Mp (e.g., PMOS transistor) and an N-type output transistor Mn (e.g., NMOS transistor), which are electrically connected in series in an order from the first supply voltage V_{dd} to the second supply voltage Vₛₛ, and are electrically connected at an output node that provides an output voltage Vₒᵤₜ .

The inverter-based comparator 500 of the embodiment may further include a resistor R that is electrically connected between the first supply voltage V_{dd} and the output stage circuit 50, and is configured to reduce large current loss generated during a transition period of the output stage circuit 50.

In the embodiment, the inverter-based comparator 500 may include a first inverter 51 having a first transition voltage V_{TR1} with an input node coupled to an input voltage Vᵢₙ and an output node generating a first inverted voltage Vn and coupled to a gate of the N-type output transistor Mn. The inverter-based comparator 500 may include a second inverter 52 having a second transition voltage V_{TR2} with an input node coupled to the input voltage Vᵢₙ and an output node generating a second inverted voltage Vp and coupled to a gate of the P-type output transistor Mp, where the second transition voltage V_{TR2} is greater than the first transition voltage V_{TR1}.

According to one aspect of the embodiment, the first inverter 51 may be implemented by the inverter 11 of FIG. 3, where the compare voltage Vₒₚ acts as the first inverted voltage Vn of the first inverter 51. Similarly, the second inverter 52 may be implemented by the inverter 11 of FIG. 3, where the compare voltage Vₒₚ acts as the second inverted voltage Vp of the second inverter 52. The circuit details of the inverter 11 of FIG. 3 are as mentioned above and are thus omitted for brevity. It is noted that the tuning signals such as the first tuning signal Dₚ₀, the second tuning signal Dₙ₀, the third tuning signal Dₚ₁ and the fourth tuning signal Dₙ₁ may be applied to generate the required first transition voltage V_{TR1} and second transition voltage V_{TR2}. According to the embodiment as described above, the inverter-based comparator 500 of FIG. 5 has hysteresis, which is adaptable to operating with a noisy input voltage Vᵢₙ in noisy environments.

FIG. 6 shows a characteristic curve when operating the inverter-based comparator 500 of FIG. 5. Specifically, under an initial condition Vₒᵤₜ=Vₛₛ, when Vᵢₙ rises and is between V_{TR1} and V_{TR2}, then Vn=Vₛₛ and Vp=V_{dd}, resulting in a latch state with the output voltage Vₒᵤₜ remaining at Vₛₛ. When Vᵢₙ continues to rise and exceeds V_{TR2}, then Vn=Vₛₛ and Vp=Vₛₛ, the output voltage Vₒᵤₜ transitioning to V_{dd}. On the other hand, under an initial condition Vₒᵤₜ=V_{dd}, when Vᵢₙ falls and is between V_{TR1} and V_{TR2}, then Vn=Vₛₛ and Vp=V_{dd}, resulting in a latch state with the output voltage Vₒᵤₜ remaining at V_{dd}. When Vᵢₙ continues to fall and is lower than V_{TR1}, then Vn=V_{dd} and Vp=V_{dd}, the output voltage Vₒᵤₜ transitioning to Vₛₛ.

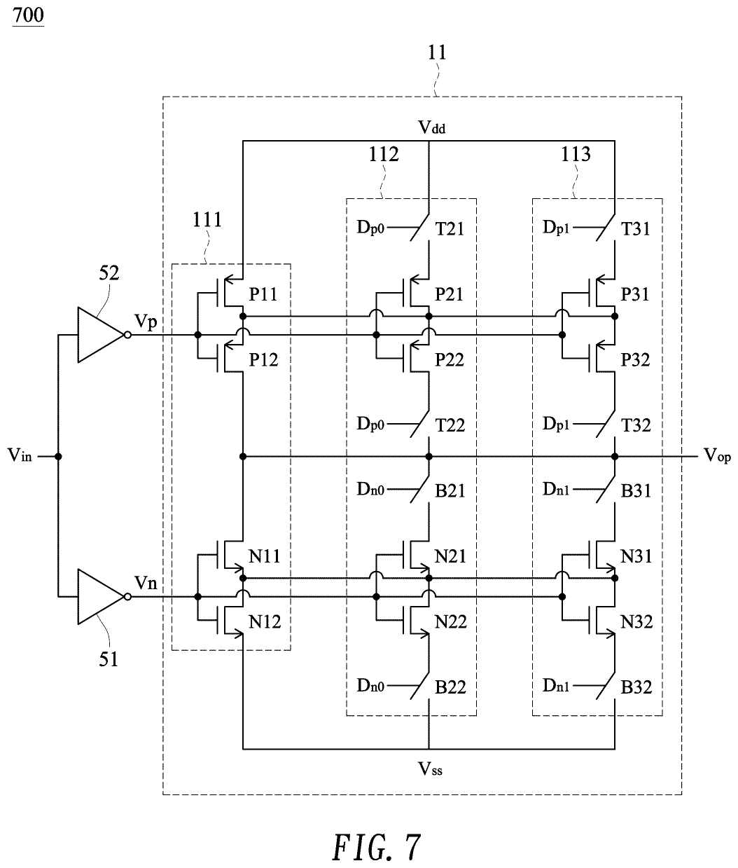

FIG. 7 shows a circuit diagram illustrating an inverter-based comparator 700 according to another embodiment of the present invention.

In the embodiment, the inverter-based comparator 700 may include an inverter 11 of FIG. 3, circuit details of which are as mentioned above and are thus omitted for brevity. The inverter-based comparator 700 may include a first inverter 51 having a first transition voltage V_{TR1} with an input node coupled to an input voltage Vᵢₙ and an output node generating a first inverted voltage Vn and coupled to gates of the series-connected first NMOS transistors N11-N12 of the first inverter branch 111, gates of the series-connected second NMOS transistors N21-N22 of the second inverter branch 112 and gates of the series-connected third NMOS transistors N31-N32 of the third inverter branch 113. The inverter-based comparator 700 may include a second inverter 52 having a second transition voltage V_{TR2} with an input node coupled to the input voltage Vᵢₙ and an output node generating a second inverted voltage Vp and coupled to gates of the series-connected first PMOS transistors P11-P12 of the first inverter branch 111, gates of the series-connected second PMOS transistors P21-P22 of the second inverter branch 112 and gates of the series-connected third PMOS transistors P31-P32 of the third inverter branch 113, where the second transition voltage V_{TR2} is greater than the first transition voltage V_{TR1}.

Although specific embodiments have been illustrated and described, it will be appreciated by those skilled in the art that various modifications may be made without departing from the scope of the present invention, which is intended to be limited solely by the appended claims.

What is claimed is:

1. An inverter-based comparator, comprising:
an output stage circuit including a P-type output transistor and an N-type output transistor electrically connected in series in an order from a first supply voltage to a second supply voltage being lower than the first supply voltage, and electrically connected at an output node that provides an output voltage;
a first inverter having a first transition voltage with an input node coupled to an input voltage and an output node generating a first inverted voltage and coupled to a gate of the N-type output transistor; and
a second inverter having a second transition voltage with an input node coupled to the input voltage and an output node generating a second inverted voltage and coupled to a gate of the P-type output transistor, the second transition voltage being greater than the first transition voltage, the first inverter and the second inverter each including an inverter that comprises:
a first inverter branch composed of at least one first P-type transistor and at least one first N-type transistor; and
a second inverter branch composed of at least one second P-type transistor, at least one second N-type transistor and at least two tuning switches;
wherein the first inverter branch and the second inverter branch are configured to compare the input voltage with an internal trigger point, thereby generating a compare voltage as an inverted voltage of the first inverter or the second inverter at an interconnected node; and
one of the at least two tuning switches is controlled to isolate the first supply voltage and another is controlled to isolate the second supply voltage to generate the first transition voltage or the second transition voltage.

2. The comparator of claim 1, wherein the second inverter branch is coupled to receive at least one tuning signal for controlling the at least two tuning switches.

3. The comparator of claim 1, wherein the at least one first P-type transistor and the at least one first N-type transistor are electrically connected in series in an order from the first supply voltage to the second supply voltage, gates of the at least one first P-type transistor and the at least one first N-type transistor are coupled to the input voltage, and the interconnected node electrically coupled between the at least one first P-type transistor and the at least one first N-type transistor provides the compare voltage.

4. The comparator of claim 1, wherein the at least one second P-type transistor and the at least one second N-type transistor are electrically connected in series in the order from the first supply voltage to the second supply voltage, gates of the at least one second P-type transistor and the at least one second N-type transistor are coupled to the input voltage, and the at least one second P-type transistor and the at least one second N-type transistor are electrically coupled at the interconnected node.

5. The comparator of claim 1, wherein the at least two tuning switches comprise:
a top switch connected between the first supply voltage and the at least one second P-type transistor or between the interconnected node and the at least one second P-type transistor; and
a bottom switch connected between the second supply voltage and the at least one second N-type transistor or between the interconnected node and the at least one second N-type transistor.

6. The comparator of claim 1, wherein the at least two tuning switches comprise:
two top switches respectively connected between the first supply voltage and the at least one second P-type transistor and between the interconnected node and the at least one second P-type transistor; and
two bottom switches respectively connected between the second supply voltage and the at least one second N-type transistor and between the interconnected node and the at least one second N-type transistor.

7. The comparator of claim 1, wherein the inverter further comprising a third inverter branch composed of at least one third P-type transistor, at least one third N-type transistor and at least two tuning switches;
wherein the at least one first P-type transistor comprises series-connected first P-type transistors, the at least one first N-type transistor comprises series-connected first N-type transistors, the at least one second P-type transistor comprises series-connected second P-type transistors, the at least one second N-type transistor comprises series-connected second N-type transistors, the at least one third P-type transistor comprises series-connected third P-type transistors, or the at least one third N-type transistor comprises series-connected third N-type transistors.

8. The comparator of claim 1, further comprising:
a resistor electrically connected between the first supply voltage and the output stage circuit.

9. An inverter-based comparator powered between a first supply voltage and a second supply voltage being lower than the first supply voltage, the comparator comprising:
a first inverter having a first transition voltage with an input node coupled to an input voltage and an output node generating a first inverted voltage;
a second inverter having a second transition voltage with an input node coupled to the input voltage and an output node generating a second inverted voltage, the second transition voltage being greater than the first transition voltage; and
an inverter composed of:
a first inverter branch composed of at least one first P-type transistor coupled to the second inverted voltage and at least one first N-type transistor coupled to the first inverted voltage; and
a second inverter branch composed of at least one second P-type transistor coupled to the second inverted voltage, at least one second N-type transistor coupled to the first inverted voltage and at least two tuning switches;
wherein the first inverter branch and the second inverter branch are configured to compare the first inverted voltage and the second inverted voltage with an internal trigger point, thereby generating a compare voltage as an output voltage at an interconnected node; and
one of the at least two tuning switches is controlled to isolate the first supply voltage and another is controlled to isolate the second supply voltage to compensate for trigger point shifting.

10. The comparator of claim 9, wherein the second inverter branch is coupled to receive at least one tuning signal for controlling the at least two tuning switches.

11. The comparator of claim 9, wherein the at least one first P-type transistor and the at least one first N-type transistor are electrically connected in series in an order from the first supply voltage to the second supply voltage, gates of the at least one first P-type transistor and the at least one first N-type transistor are coupled to the second inverted voltage and the first inverted voltage respectively, and the interconnected node electrically coupled between the at least one first P-type transistor and the at least one first N-type transistor provides the compare voltage.

12. The comparator of claim 9, wherein the at least one second P-type transistor and the at least one second N-type transistor are electrically connected in series in the order from the first supply voltage to the second supply voltage, gates of the at least one second P-type transistor and the at least one second N-type transistor are coupled to the second inverted voltage and the first inverted voltage respectively, and the at least one second P-type transistor and the at least one second N-type transistor are electrically coupled at the interconnected node.

13. The comparator of claim 9, wherein the at least two tuning switches comprise:
a top switch connected between the first supply voltage and the at least one second P-type transistor or between the interconnected node and the at least one second P-type transistor; and
a bottom switch connected between the second supply voltage and the at least one second N-type transistor or between the interconnected node and the at least one second N-type transistor.

14. The comparator of claim 9, wherein the at least two tuning switches comprise:
two top switches respectively connected between the first supply voltage and the at least one second P-type transistor and between the interconnected node and the at least one second P-type transistor; and
two bottom switches respectively connected between the second supply voltage and the at least one second N-type transistor and between the interconnected node and the at least one second N-type transistor.

15. The comparator of claim 9, wherein the inverter further comprising a third inverter branch composed of at least one third P-type transistor, at least one third N-type transistor and at least two tuning switches;
wherein the at least one first P-type transistor comprises series-connected first P-type transistors, the at least one first N-type transistor comprises series-connected first N-type transistors, the at least one second P-type transistor comprises series-connected second P-type transistors, the at least one second N-type transistor comprises series-connected second N-type transistors, the at least one third P-type transistor comprises series-connected third P-type transistors, or the at least one third N-type transistor comprises series-connected third N-type transistors.
